(19) United States
(12) Patent Application Publication
(10) Pub. No.: US 2018/0210049 A1
(43) Pub. Date: Jul. 26, 2018

(54) LOCAL COIL DEVICE FOR A HEAD OF A PATIENT, SHIM COIL DEVICE AND METHOD FOR COMPENSATING BASIC FIELD INHOMOGENEITIES IN A REGION OF INTEREST OF THE PREFRONTAL CORTEX OF THE PATIENT

(71) Applicant: Stephan Biber, Erlangen (DE)

(72) Inventor: Stephan Biber, Erlangen (DE)

(21) Appl. No.: 15/876,136

(22) Filed: Jan. 20, 2018

(30) Foreign Application Priority Data
Jan. 20, 2017 (DE) 102017200960.8

(51) Int. Cl. G01R 33/3875; G01R 33/341

(52) U.S. Cl. CPC G01R 33/3875; G01R 33/341

(57) ABSTRACT

A local coil device for a head of a patient for use in a magnetic resonance device includes a local coil with at least one local coil element and a receiver for the head of the patient in which the head may be received in a desired pose. The local coil device also includes a shim coil device with at least one shim coil element for compensating basic field inhomogeneities in a region of interest of the prefrontal cortex of the patient. With respect to the desired pose, the shim coil element of the shim coil device integrated in the local coil or received in a receiver for the shim coil device is arranged anterior to the head.

This application claims the benefit of DE 10 2017 200 960.8, filed on Jan. 20, 2017, which is hereby incorporated by reference in its entirety.

### BACKGROUND

The present embodiments relate to a local coil device for a head of a patient for use in a magnetic resonance device, a shim coil device, and a method for compensating basic field inhomogeneities in a region of interest.

Magnetic resonance imaging is an imaging modality that has become established in medical technology. In this connection, a strong magnetic basic field that may be modified by the gradients for spatial resolution is generated inside a patient receiver of the magnetic resonance device used. With excitation of nuclear spins oriented in the basic field, magnetic resonance signals are produced as response signals, and these may be received via suitable receiver coil arrangements while the excitation is output via transmitter coil arrangements that are optionally identical to the receiver coil arrangements.

For examining different body regions of a patient, for increasing the signal-to-noise ratio and for accelerating the scan time, local coils with at least one local coil element as the transmitter coil arrangement and/or receiver coil arrangement may be used. Antennae structures of this kind are locally positioned close to the body of the patient and/or may have appropriate receivers for body parts of the patient. For example, local head coils that may be placed on an examination table that is to be moved into the patient receiver and with which the head of the patient is to be optimally received in a desired pose (e.g., desired orientation and desired position) in the local coil, where, for example, the upper part of the local coil may have a hinged design or the like have been provided.

The homogeneity of the basic field (B0 field) in the scan region plays a decisive role for the image quality in many imaging techniques. A high basic field homogeneity is to be provided, for example, in order to avoid or reduce signal losses or geometric distortions (fat/water shift) in the case of EPI imaging.

Superconducting magnets that allow magnetic field homogeneities having deviations of less than 1 ppm over a volume of approximately 30×40×50 cm may be used as basic field magnets in current (e.g., cylindrical) magnetic resonance devices. Problems, for example, with fat saturation may therefore result in particular in regions of the anatomy located a long way away (e.g., on the shoulder) that, owing to the lack of available space in the patient receiver of a magnetic resonance device, may not be centrally positioned either.

More critical than the known and deterministic basic field inhomogeneities are those introduced by the patients themselves (e.g., tissue), however. Human tissue has a relative magnetic permeability that is different from 1.0. As a result, discontinuities of air and tissue, for example, lead to severe basic field distortions, and therefore, field inhomogeneities. The inhomogeneous distribution of water/air/bones/fat in the human body may lead to a distortion of the basic field that is different for each patient. These kinds of locally occurring field inhomogeneities in the basic field of the magnetic resonance device, for example, that are different from patient to patient, moreover, may only be inadequately corrected by a general shim device that is usually arranged so as to surround the patient receiver and conventionally compensates the deterministic basic field inhomogeneities based on of the ever-present components of the magnetic resonance device. It has therefore been proposed to also use local shim devices, provided, for example, as shim coil devices. DE 10 2011 077 724 A1, for example, therefore proposes the use of a local shim coil inside a local coil for local basic field homogenization in a magnetic resonance device, with the specific application referring to the cervical spine.

A further critical position is the region of the prefrontal cortex of a patient. Due to the air in the frontal sinuses and paranasal sinuses, magnetic inhomogeneities of the basic field that have an adverse effect on imaging in the region of interest of the prefrontal cortex occur. An exact description of this problem may be found, for example, in an article by Jason P. Stockmann et al., “32-Channel Combined RF and B₀ Shim Array for 3T Brain Imaging,” Magnetic Resonance in Medicine 75: 441-451 (2016).

Various approaches have already been proposed to improve imaging of the prefrontal cortex by shim measures that reduce basic field inhomogeneities. Therefore, the article by Jason P. Stockmann et al., for example, proposes providing shim measures slice for slice in order to improve the shim situation with respect to a volume-based optimization. The problem of in-plane basic field inhomogeneities, for example, in a transversal slice, is not solved here, however. Both the article by Jason P. Stockmann et al. and an article by Christoph Juchem et al., “Dynamic multi-coil technique (DYNAMITE) shimming for echo-planar imaging of the human brain at 7 Tesla,” Neurolmage 105 (2015), pages 462-472, propose the use of local shim arrays that extend around the head of the patient. Complex control of the large number of local shim coil elements is intended to create correction fields that compensate the basic field inhomogeneities. However, these are extremely complex arrangements that are difficult to handle that, moreover, with the use of shim coil elements of the third to fifth order entail as further drawbacks a high inductance, diminishing efficiency in the case of higher orders and expensive shim current supplies.

In a further approach, an article by James L. Wilson and Peter Jezzard, “Utilization of an Intra-Oral Diamagnetic Passive Shim in Functional MRI of the Inferior Frontal Cortex,” Magnetic Resonance in Medicine 50:1089-1094 (2003) proposes using a passive shim that is to be introduced into the oral cavity of a patient. However, this is difficult to adapt to specific circumstances and it is usually undesirable, moreover, to provide shim devices that are to be placed inside the patient.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a less complex and effective possibility that is easy to implement for compensating basic field inhomogeneities in the case of scans in the region of the prefrontal cortex is provided.

In the case of a local coil device of the type mentioned in the introduction that with respect to the desired pose, the shim coil element of the shim coil device integrated in the local coil or received in a receiver for the shim coil device is arranged anterior to the head.

The number of shim coil elements is kept low, and all shim coil elements are provided only anterior to the head. In other words, the shim coil device of the local coil device of one or more of the present embodiments has only shim coil elements arranged anterior to the head. In investigations on basic field inhomogeneity and inhomogeneities that occur due to the presence of a human head, basic field inhomogeneities that are induced by the anatomy of the patient tend to occur in the front region of the brain and are very localized there. The anatomical variability compared to other regions of the body (e.g., the chest) tends to be low. Owing to the strong localization of the basic field inhomogeneities that occur in the rostral region of the head, it is sufficient to use shim coil elements arranged anterior to the head (e.g., in front of the face), and these may be low in number. Just a single shim coil element may thus be used.

In one embodiment, a shim coil arrangement includes one or several, optionally individually controllable, shim coil elements to be arranged on the anterior side of the head. The geometry of the shim coil elements, which will be discussed in more detail below, is configured such that the anatomically generated basic field distortion may be compensated with an optimally small number of independent sources, and therefore, shim coil elements, so the situation is avoided where the head is surrounded by any number of shim coil elements. It is hoped that a linear combination of shim fields may compensate the desired inhomogeneity. This results in a decisive advantage for the costs that are connected with the development and production of the shim coil device.

In the present case, local coil elements are not used as shim coil elements. This provides that the at least one shim coil element and the at least one local coil element are metallically isolated. The at least one shim coil element may also have a radio frequency choke for decoupling from the local coil element. This provides the shim coil elements are isolated by radio frequency chokes, which offer high resistance at frequencies in an interval around the Larmor frequency, from the local coil elements of the local coil device that serve as receiver coil elements and/or transmitter coil elements. The shim coil elements are configured as conductive paths metallically isolated from the local coil elements.

In one embodiment, the shim coil device may be provided as a part that may be isolated from the local coil device. For this purpose, a corresponding receiver, formed, for example, by a holding mechanism and/or an indentation, for the shim coil device is then formed on the local coil. The shim coil device may therefore be mechanically removed and may also be configured so as to be adjustable relative to the local coil (e.g., head coil). This kind of adjustability enables an alignment of the shim coil element position relative to the actual position of the anatomy inside the local coil or on the examination table. A removable shim coil device has the advantage that, when it is not required, the field of vision of the patient may be kept freer and this is not unnecessarily limited or strained by additional material in his surroundings.

However, in one embodiment, the shim coil device may be permanently integrated in the housing of the local coil, so clearly defined positions of the shim coil elements may therefore be provided relative to the desired position, even in the case of basically moveable shim coil elements.

In one embodiment, at least one of the at least one shim coil elements may have just one winding, and at least one of the at least one shim coil elements may have a plurality of windings. Shim coil elements used within the context of the present embodiments may therefore have one or more windings in order to optimally balance the expenditure resulting from power generation and cable routing and the expenditure for radio frequency decoupling and coil sensitivity. Specifically, this provides that in order to generate a particular desired shim field, less shim current is required in the case of more windings, but a larger number of radio frequency chokes is necessary for decoupling. Although in the case of a small number of (e.g., one) windings, fewer radio frequency chokes are required for decoupling, a higher shim current is to be generated, and the radio frequency chokes are more complex in design owing to the higher shim current. A suitable optimum may be found.

In one embodiment, the at least one shim coil element extends in a plane parallel to a frontal plane of the head with respect to the desired pose. The greatest amount of free space exists in this plane for the optional arrangement of shim coil elements of different sizes as well. In one embodiment, one field component relevant in the direction of the basic magnetic field (e.g., which corresponds to the cranial-caudal direction in respect of the desired pose) may be generated extremely locally for compensation by clever design of the geometry of the at least one shim coil element, with the remaining field components running in a direction that is less relevant or not relevant to imaging.

For the majority of magnetic resonance devices, the directions defined with respect to the desired pose of the head may also be mapped to the system directions there. In a magnetic resonance device having a cylindrical patient receiver, the reclining patient is moved in the longitudinal direction of the patient receiver (z direction). The z direction is also the direction of the basic magnetic field in the homogeneity volume of the magnetic resonance device. The z direction at least essentially corresponds to the cranial-caudal direction of the patient. In a magnetic resonance device, the direction perpendicular to the z direction and running vertically is conventionally called the y direction. With respect to the head, the z direction at least essentially corresponds to the anterior-posterior direction. The remaining direction, perpendicular to the z direction and the y direction and running horizontally is referred to as the x direction. In this nomenclature, the at least one shim coil element may be configured to extend in a z-x plane since the patient is conventionally moved into the patient receiver lying on his back.

A development of the present embodiments in this context provides that at least one of the at least one shim coil elements is configured as a connected or separated butterfly coil having current loops that follow each other in the cranial-caudal direction in relation to the desired pose. A butterfly coil is characterized in that the butterfly coil forms two current loops that follow each other in one direction, through which current may flow in opposite directions. This may occur either in that, in the case of a connected butterfly coil, the conductive paths of the butterfly coil run in the manner of an infinity symbol, or separated butterfly coils may also be provided in which the individual current loops that follow each other in one direction are metallically isolated but are basically supplied with current in opposite directions to each other. The cranial-caudal direction corresponds again at least essentially to the z direction, where, owing to geometry, butterfly coils have a characteristic that makes it possible to generate a shim field or compensation field in the cranial-caudal direction or z direction in a highly localized region below or above the center point between the current loops. Outside of this highly localized region, the field direction of the shim field bends rapidly in an anterior-posterior direction (e.g., the y direction), which is hardly relevant or not relevant to imaging, however. Compensating shim fields may therefore be purposefully and easily generated in the z direction for the highly localized basic field inhomogeneities induced by the anatomy in the front region of the head (e.g., also with just a single shim coil element), which is accordingly configured as a butterfly coil.

In one development, the metallically isolated coil sections of the separated butterfly coil, which are supplied with current in opposite directions and follow each other in the cranial-caudal direction with respect to the desired pose, may be supplied with current independently, but basically in opposite directions. The ratio of the current strengths of the different introduced shim currents determines the form of the shim field, and this may be used for adjustment to the individual anatomy of a patient for current examination. A further degree of freedom is therefore created in this way.

The following also applies to the butterfly coil: windings may be provided for each of the current loops. The current loops having radio frequency chokes in series may be protected against coupling to the radio frequency field of the local coil elements.

In one embodiment, the shim coil element is arranged on a support moveably guided in at least one direction by a guide device. The guide device may be configured, for example, as a sliding bearing and/or may include guide rails. Adjustment to a pose, different from the desired position, of a head for current scanning and/or the individual patient anatomy is possible in this way. Since the at least one shim coil element (e.g., configured as a butterfly coil) generates a shim field (e.g., a highly localized shim field) in the z direction (e.g., the direction of the basic magnetic field), an adjustment to the position of the basic field inhomogeneity to be compensated may be made in the case of movement in this z direction. This also applies to other directions in which, albeit less preferred, movement may be produced (e.g., the x direction and/or said y direction). The support may be moveably guided in a cranial-caudal direction relative to the desired pose. As has been illustrated, the cranial-caudal direction corresponds to the z direction of the magnetic resonance device and therefore the direction of the basic magnetic field or the longitudinal direction of the cylindrical patient receiver.

Alternatively or additionally, the shim coil device may have a plurality of shim coil elements offset, for example, in at least one direction. If a single shim coil element is not sufficient to carry out an adequate compensation of basic field inhomogeneities that is individual to the patient and/or a movement in different directions may only be achieved in a complicated manner, shim coil elements that are arranged staggered in one direction (e.g., in directions for which no movement exists) may be used. For example, in one embodiment, for at least one shim coil element that extends in a plane parallel to a frontal plane of the head with respect to the desired pose, at least one further shim coil element is provided that is offset only in an anterior-posterior direction of the head defined with respect to the desired pose, and/or an array of shim coil elements is provided that extends in a plane (e.g., with respect to the desired pose in a plane parallel to a frontal plane of the head). In each case, a “stack” of shim coil elements may thus be provided in the anterior-posterior direction, for example, so a variation in the position of the shim field in depth, conventionally the y direction, may occur by choosing appropriate shim coil elements to be supplied with current. In one embodiment, arrays of shim coil elements that follow each other, for example, in the z direction (e.g., cranial-caudal direction) or in the x direction (e.g., lateral) may be provided in a plane parallel to a frontal plane of the head (e.g., a z-x plane) to enable an adjustment of the position of the shim field that is individual to the patient and therefore compensation that is individual to the patient. At least one suitable shim coil element may, for example, accordingly also be selected. Excellent adjustment to the specific patient anatomy currently at hand, or head pose, is therefore possible, as is also the case with movement in at least one direction.

The shim coil device may have at least one switching device for choosing shim coil elements that are to be supplied with current and/or for distributing a basic current among shim currents feeding a plurality of different shim coil elements. The switching device may be configured, for example, as a switching matrix and/or may include an adjustable resistance. Switching matrices have also been proposed for use in shim coils, where reference is made, by way of example, to DE 10 2011 087 485 B3. It is thereby possible to switch a shim channel (e.g., providing a shim current) to at least one of the selectable shim coil elements. Instead of straightforward switching, or in addition thereto, an adjustable resistance may be used in a switching device that divides a basic current among a plurality of shim currents feeding different shim coil elements, whereby shim channels may likewise be reduced yet different shim coil elements may be supplied with different currents. The number of required shim channels may again be reduced, moreover, in that at least two of the shim coil elements are connected in parallel and/or at least two of the shim coil elements are connected in series. This enables a compromise between the maximum flexibility for adjustment to the anatomy and the expenditure, associated with current sources and cable costs, of a large number of independent shim coil elements.

In the context of the present embodiments, a separate current source may be allocated to each shim coil element of the shim coil device in order to control all shim coil elements independently and therefore have the greatest possible scope available for adjustment to the anatomy for current scanning and/or the actual current pose (e.g., when a small number of shim coil elements is used).

In order to control operation of the shim coil device, the local coil device (e.g., also the shim coil device itself) may include a controller configured for choosing a position of the movable support and/or for choosing at least one of the plurality of shim coil elements to be supplied with current (e.g., by controlling the switching device) and/or for determining and applying a shim current to at least one of the at least one shim coil elements as a function of an item of patient information describing the anatomy and/or pose of the head of a patient for current recording. For example, the controller may be provided with an item of patient information, so the controller may derive ideal settings for the operation of the shim coil elements herefrom to enable optimum compensation of field distortions of the basic field (B0 field) of the magnetic resonance device generated by the anatomy.

In addition to the local coil device, the present embodiments also relate to a shim coil device for compensating inhomogeneities in a region of interest of the prefrontal cortex of a patient in a magnetic resonance device, having at least one shim coil element that is characterized in that the shim coil elements are arranged anterior to the head of the patient. For example, an arranger may be configured such that the shim coil device is configured for arrangement in a receiver for a shim coil device of a local coil device.

All statements relating to the local coil device may also be analogously transferred to the shim coil device with which therefore the advantages already mentioned may likewise be achieved.

The present embodiments also relate to a method for compensating basic field inhomogeneities in a region of interest of the prefrontal cortex of a patient in a magnetic resonance device. At least one shim coil element of a shim coil arrangement is supplied with current for homogenization of the basic field in the region of interest. The method is characterized in that the shim coil element is arranged anterior to the head of the patient. A method of shimming that only uses shim coil elements arranged anterior to the head is therefore provided. The statements relating to the local coil device and shim coil device may also be analogously transferred to the method.

### BRIEF DESCRIPTION OF THE DRAWINGS

FIG. 1 shows a schematic diagram relating to a first embodiment of a local coil device;

FIG. 2 shows a schematic diagram relating to a second embodiment of a local coil device;

FIG. 3 shows a first embodiment of a usable shim coil element;

FIG. 4 shows a second embodiment of a usable shim coil element;

FIG. 5 shows a view relating to a position of a shim coil elements relative to the head of a patient;

FIG. 6 shows a diagram to illustrate the generation of a compensating shim field;

FIG. 7 shows one embodiment of an arrangement of shim coil elements in an array;

FIG. 8 shows a first possibility for controlling shim coil elements;

FIG. 9 shows a second possibility for controlling shim coil elements; and

FIG. 10 shows one embodiment of an arrangement of the local coil device in a magnetic resonance device.

### DETAILED DESCRIPTION

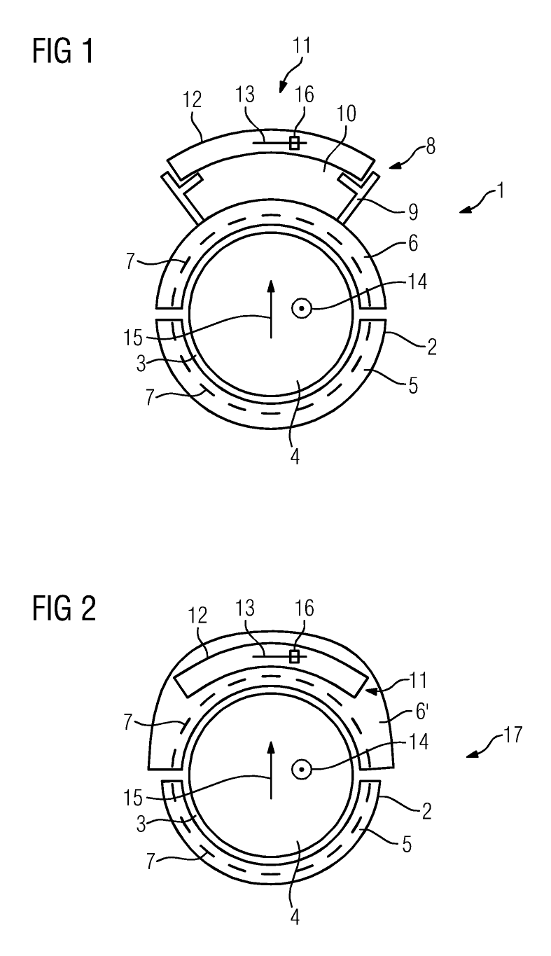

FIG. 1 shows a first exemplary embodiment of a local coil device 1. The local coil device 1 includes a local coil 2 (e.g., a head coil) that has a receiver 3 for a head 4 of a patient to be examined, indicated in FIG. 1 in a desired pose. In the present case, the local coil 2 has a lower housing part 5 and an upper housing part 6 in which local coil elements 7 that are each only indicated in FIG. 1 are arranged. The local coil elements 7 may be operated as receiver coils and/or transmitter coils in order to be able to record high-quality images having, for example, a lower signal-to-noise ratio, of a head 4 received in the receiver 3 with a magnetic resonance device (not shown). A holding mechanism 9, which may also be used as a guide device 8, is provided on the housing part 6 and forms a receiver 10 for a shim coil device 11. The shim coil device 11 may be removably inserted in the receiver 10. The shim coil device 11 includes a support 12, in which at least one shim coil element 13 is cast. The support 12 may be moved in the guide device 8 in the cranial-caudal direction 14 of the head 4 in the desired pose that is perpendicular to the drawing plane according to FIG. 1, which may also correspond to the z direction of the magnetic resonance device in which the local coil device 1 is to be inserted, and therefore, the direction of the basic field of the magnetic resonance device. The at least one shim coil element 13 may therefore be moved to different positions in the cranial-caudal direction 14.

The at least one shim coil element 13 is used for generating a shim field to compensate field inhomogeneities of the basic field that result due to the anatomy of the head 4 (e.g., the air in the frontal sinuses and paranasal sinuses), which may reduce the image quality, for example, in the case of recordings of the prefrontal cortex. To achieve this, the shim coil element 13 is arranged anterior to the head 4 having a rostral direction 15 that is likewise shown in FIG. 1 for orientation. The at least one shim coil element 13 is metallically isolated from the local coil elements 7 and has at least one radio frequency choke 16 to achieve radio frequency decoupling from the local coil elements 7. The radio frequency choke 16 has a high blocking resistance in a region around the Larmor frequency of the magnetic resonance device.

Before possible embodiments and effects of the at least one shim coil element 13 are to be discussed in more detail, FIG. 2 shows an alternative embodiment of a local coil device 17. Same components are provided with same reference numerals for the sake of simplicity.

In contrast to the embodiment in FIG. 1, the shim coil device 11 is integrated in the local coil 2, for which purpose the upper housing part 6′ is enlarged in order to be able to receive the support 12 having the at least one shim coil element. However, the support 12 is also moveably mounted in the cranial-caudal direction 14 in order to be able to carry out adjustments to the specific position and anatomy of a head 4 for current recording. As shown, the shim coil element 13 is located anterior to the head 4 in this way as well.

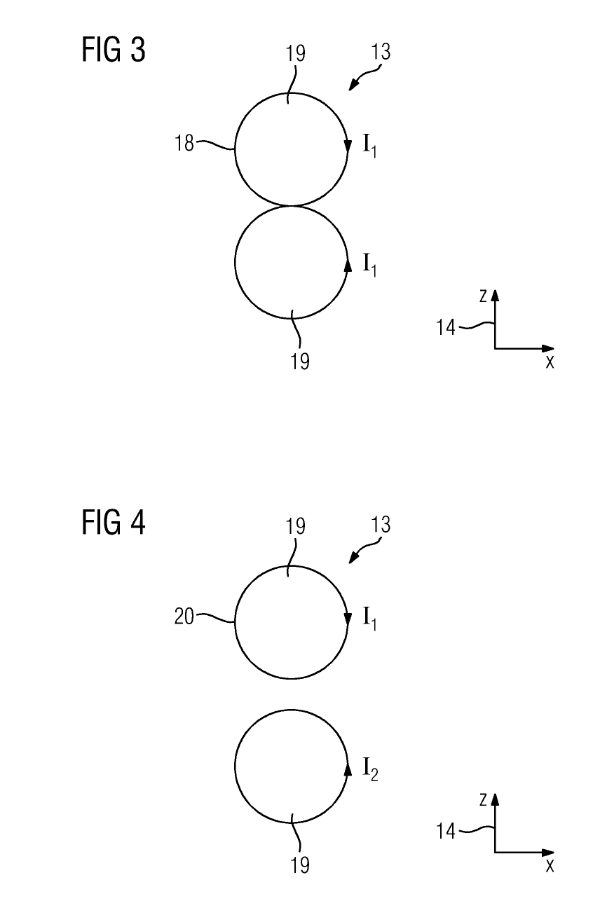

FIG. 3 shows a first possible embodiment of the at least one shim coil element 13, as may be used in the local coil devices 1, 17. As shown, the shim coil element 13 is configured as a connected butterfly coil 18 that, therefore, as is basically known, has two current loops 19 that are electrically connected in such a way that a shim current I₁ conducted through the butterfly coil 18 flows in opposite directions in each of the two current loops 19. As the alternative embodiment in FIG. 4 shows, the individual current loops 19 may also be implemented as separate coil sections 20, through which different currents I₁, I₂ that are always oriented in opposing directions, may then also flow.

The illustrated shim coil elements 13 extend in a plane parallel to a frontal plane of the head 4, therefore a horizontal plane, which is spanned by the cranial-caudal direction 14 or z direction and a horizontal direction (x direction of the magnetic resonance device) perpendicular thereto. The current loops 19 are arranged in the z direction so as to follow each other. FIG. 5 shows this arrangement relative to the head 4 again with respect to the butterfly coil 18 in a coronal view.

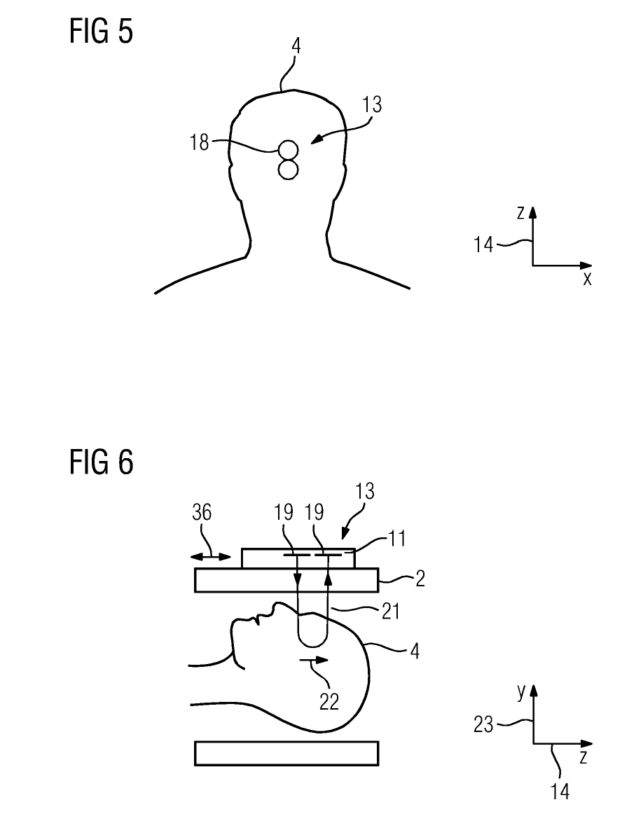

The schematic sagittal view in FIG. 6 outlines the mode of operation of the shim coil element 13 configured as a butterfly coil 18 in FIG. 3 or FIG. 4 again in more detail. The head 4 is shown inside the local coil 2, anterior to which the shim coil device 11 having the shim coil element 13 is arranged. Overlaying of the fields of the current loops 19 with different orientations produces a shim field course 21 that has a highly localized component, oriented in the z direction and symbolized by the arrow 22, which merge fairly quickly again into components in the y direction or to the anterior-posterior direction 23 with respect to the desired position of the head 4, and therefore do not affect imaging, or at least not in a relevant way. With the shim coil element 13, the localized, strong inhomogeneities in the basic field caused by the anatomy of the head 4 may therefore be compensated. Different positions of the inhomogeneities in the z direction due to the movement of the shim coil element 13 indicated by the double arrow 36 may be taken into account.

With a change in the ratio of I₁ and I₂ in the case of the separated butterfly coil 18 in FIG. 4, the field form may also be adjusted to the individual anatomy of a head 4 for current recording.

The current loops 19 (and therefore also the entire butterfly coil 18) may have a plurality of windings with which, for example, radio frequency chokes 16 may in each case be associated.

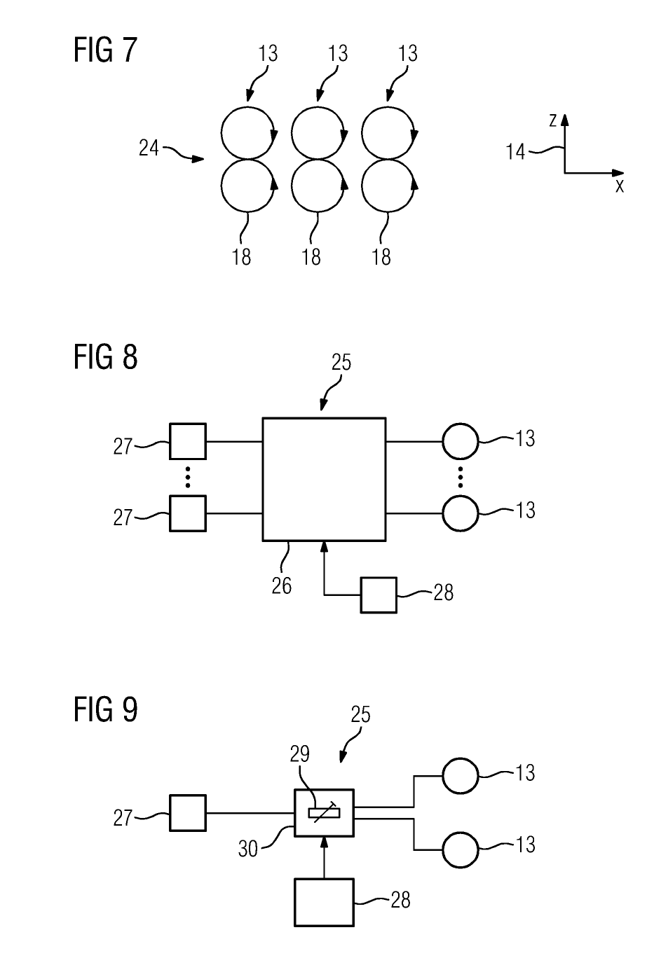

A plurality of shim coil elements 13 may also be arranged in a shim coil device 11 to optionally be able to achieve, in addition to a movement, an adjustment to the anatomy and position of the head 4 for current recording by choosing the shim coil elements 13 to be supplied with current and/or determining suitable shim currents for the shim coil elements 13 to be supplied with overcurrent. For this, it may, for example, be provided that a plurality of shim coil elements 13 arranged congruently one above the other in the y direction is used as a “stack”; as is shown in FIG. 7, arrays 24 of shim coil elements 13 (e.g., butterfly coils 18) may be arranged in other directions in the z-x plane, in the x direction in FIG. 7. To switch shim currents to a plurality of shim coil elements 13 (e.g., if a small number of shim channels/current sources exist as shim coil elements 13), a switching device may be used, with exemplary embodiments being shown in FIGS. 8 and 9. FIG. 8 shows a configuration of the switching device 25 as a switching matrix 26 that may selectively connect a number of current sources 27 to a number of shim coil elements 13. Operation of the switching device 25 is controlled by a controller 28 that may use, for example, an item of patient information describing the anatomy and pose (e.g., position and orientation) of the head for current examination in order to determine shim coil elements to be supplied with current 13 and shim currents such that optimum compensation of basic field distortions caused by the anatomy is achieved. Such an item of patient information may includes, for example, a B0 field map (basic field map) from which, by the known shim field generating properties of the shim coil elements 13, corresponding compensation configurations and control signals derived therefrom, (e.g., also at the current sources 27) may be generated.

FIG. 9 shows a variant that may optionally also be used in addition to the embodiment according to FIG. 8, in which a current divider 30 having an adjustable resistor 29 is used as switching device 25 in order to divide a basic current into two different shim currents for different shim coil elements 13. This process is also controlled by the controller 28.

The controller 28 does not have to be part of the shim coil device 11 or the local coil device 1, 17 but may also be provided externally, for example, as part of the magnetic resonance device, so the control signals may then be routed via appropriate control lines to the switching devices 25.

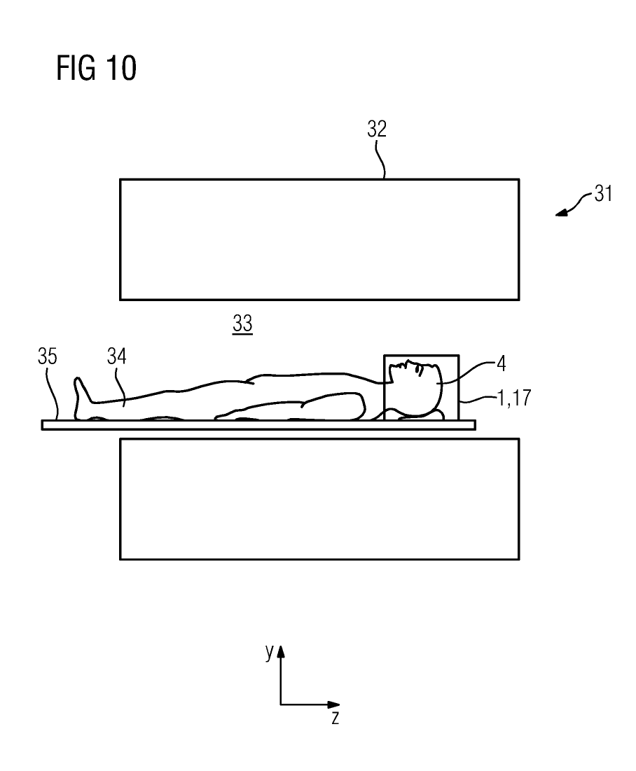

FIG. 10 shows the arrangement of one embodiment of a local coil device 1, 17 inside a magnetic resonance device 31 that is shown schematically in cross-section. The magnetic resonance device 31 includes a main magnet unit 32 in which a patient receiver 33 is formed. The main magnet unit 32 contains the superconducting main magnet generating the basic field, with a gradient coil arrangement and a radio frequency coil arrangement (e.g., body coil) often also being provided so as to surround the patient receiver 33. A patient 34, whose head is to be recorded, may be moved by an examination table 35 into the patient receiver 33. The head 4 and the local coil device 1, 17 surrounding the head 4 are positioned in the homogeneity volume of the magnetic resonance device 31 to perform the scans. Shimming of inhomogeneities in the basic field, induced by the anatomy, occurs in the prefrontal cortex region by the shim coil device 11 during recording of the magnetic resonance data.

Although the invention has been illustrated and described in detail by the exemplary embodiments, the invention is not limited by the disclosed examples, and a person skilled in the art may derive other variations herefrom without departing from the scope of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil device for a head of a patient for use in a magnetic resonance device, the local coil device comprising:
a local coil including at least one local coil element and a receiver for the head of the patient in which the head is receivable in a desired pose; and
a shim coil device including at least one shim coil element for compensating basic field inhomogeneities in a region of interest of the prefrontal cortex of the patient,
wherein with respect to the desired pose, the at least one shim coil element of the shim coil device integrated in the local coil or received in a receiver for the shim coil device is arranged anterior to the head.

2. The local coil device of claim 1, wherein the at least one shim coil element and the at least one local coil element are metallically isolated, the at least one shim coil element has a radio frequency choke for decoupling from the at least one local coil element, or the at least one shim coil element and the at least one local coil element are metallically isolated and the at least one shim coil element has a radio frequency choke for decoupling from the at least one local coil element.

3. The local coil device of claim 1, wherein one or more shim coil elements of the at least one shim coil element has just one winding, one or more shim coil elements of the at least one shim coil element has a plurality of windings, or one or more shim coil elements of the at least one shim coil element has just one winding and one or more shim coil elements of the at least one shim coil element has a plurality of windings.

4. The local coil device of claim 2, wherein with respect to the desired pose, the at least one shim coil element extends in a plane parallel to a frontal plane of the head.

5. The local coil device of claim 4, wherein one or more shim coil elements of the at least one shim coil element is configured as a connected or separated butterfly coil having current loops that follow each other in a cranial-caudal direction in relation to the desired pose.

6. The local coil device of claim 5, wherein two metallically isolated coil sections of the separated butterfly coil that are supplied with current in opposite directions and follow each other in the cranial-caudal direction in relation to the desired pose are suppliable with current independently but essentially in opposite directions.

7. The local coil device of claim 1, wherein the at least one shim coil element is arranged on a support moveably guided in at least one direction by a guide device.

8. The local coil device of claim 7, wherein the support is moveably guided in a cranial-caudal direction relative to the desired pose.

9. The local coil device of claim 1, wherein the at least one shim coil element includes a plurality of shim coil elements offset in at least one direction.

10. The local coil device of claim 9, wherein for one or more shim coil elements of the at least one shim coil element extending in a plane parallel to a frontal plane of the head with respect to the desired pose, at least one further shim coil element of the at least one shim coil element is provided that is offset only in an anterior-posterior direction of the head defined with respect to the desired pose, an array of shim coil elements of the at least one shim coil element that extends in a plane is provided, or a combination thereof.

11. The local coil device of claim 10, wherein the array of shim coil elements of the at least one shim coil element extends in a plane with respect to the desired pose in a plane parallel to a frontal plane of the head.

12. The local coil device of claim 8, wherein the shim coil device further includes at least one switching device for choosing shim coil elements of the at least one shim coil element to be supplied with current, for distributing a basic current among a plurality of shim currents to be fed to different shim coil elements of the at least one shim coil element, or for a combination thereof, at least two shim coil elements of the at least one shim coil element are connected in parallel, at least two shim coil elements of the at least one shim coil element are connected in series, or any combination thereof.

13. The local coil device of claim 7, further comprising a controller configured to:
choose a position of the moveable support;
choose one or more shim coil elements of the at least one shim coil element to be supplied with current;
determine and apply a shim current to one or more shim coil elements of the at least one shim coil element as a function of an item of patient information describing anatomy, the pose of the head of the patient for current recording, or the anatomy and the pose of the head; or
any combination thereof.

14. The local coil device of claim 13, wherein the shim coil device further includes a switching device, and
wherein the controller is configured to choose one or more shim coil elements of the at least one shim coil element to be supplied with current by controlling the switching device.

15. A shim coil device for compensating basic field inhomogeneities in a region of interest of the prefrontal cortex of a patient in a magnetic resonance device, the shim coil device comprising:
at least one shim coil element,
wherein the at least one shim coil element is arrangeable anterior to the head of the patient.

16. The shim coil device of claim 15, wherein the shim coil device is configured for arrangement in a receiver for the shim coil device of a local coil device, the local coil device comprising:
a local coil including at least one local coil element and a receiver for the head of the patient in which the head is receivable in a desired pose.

17. A method for compensating basic field inhomogeneities in a region of interest of the prefrontal cortex of a patient in a magnetic resonance device, the method comprising:
supplying at least one shim coil element of a shim coil arrangement with current for homogenization of a basic field in the region of interest,
wherein the at least one shim coil element is arranged anterior to the head of the patient.
